(19) United States
(12) Patent Application Publication
(10) Pub. No.: US 2013/0193976 A1
(43) Pub. Date: Aug. 1, 2013

(54) LABEL WITH ON-BATTERY VOLTAGE INDICATOR

(71) Applicant: Sancoa International Company, L.P., Lumberton, NJ (US)

(72) Inventors: Barry Hostetter, Landenberg, PA (US); Ulrich E. Weyermann, Bethany Beach, DE (US); Barron G. McKillip, Mickleton, NJ (US)

(73) Assignee: SANCOA INTERNATIONAL COMPANY, L.P., Lumberton, NJ (US)

(21) Appl. No.: 13/751,231

(22) Filed: Jan. 28, 2013

Related U.S. Application Data
(60) Provisional application No. 61/591,014, filed on Jan. 26, 2012.

(51) Int. Cl. G01R 31/36

(52) U.S. Cl. CPC G01R 31/362
USPC 324/427

(57) ABSTRACT

The present invention is a shrink label with a die cut voltage indicator device integrated therewith.

### This application is claims the benefit of priority of U.S. Ser. No. 61/591,014, filed Jan. 26, 2012, which is incorporated herein by reference in its entirety.

### BACKGROUND OF THE INVENTION

Dry cell batteries have a finite service life and show little indication of remaining electrical energy until near the end of functional service. For this reason, it is useful to employ a voltage test indicator and in particular a voltage test indicator that is incorporated into individual batteries, ideally a voltage test indicator incorporated in the battery label.

General approaches for on battery voltage indicators have been disclosed in the following documents: U.S. Pat. Nos. 4,723,656, 4,835,475, 5,059,895, 5,128,616, 5,188,231, 5,389,458, 5,612,151, 5,709,962, 5,925,480, and 6,054,234; and US Application Nos. 2004/0157027 and 2011/0163752.

One approach for on battery voltage indicators has the function of indicating battery voltage level by manually connecting the indicator with the positive and negative ends of the battery, which in turn generates heat through a resistor circuit. This generated heat then activates a thermochromic ink, which turns from a dark color (black) to a clear color thereby revealing a color underneath the thermochromic ink indicative of the battery voltage level. The design of the resistor circuit and other components are functionally effective to indicate the remaining electrical energy or voltage in the battery.

On battery voltage indicators that utilize a heat generating resistor circuit that is calibrated to respond as a function of the battery's residual electrical energy or voltage which corresponding activates a color change of a thermochromic ink have been described. The design and process of producing these devices on a commercial scale typically includes several key components such as a conductive ink, thermochromic ink and insulator to thermally isolate the battery from the resistor circuit. Practical considerations such as high temperature curing of the conductive ink require the voltage indicator device to be produced independently from the battery label and subsequently combined with the label in one or more processes. In most approaches, the voltage indicator is produced in multiple steps, some with components of the voltage indicator applied to the label, some with components produced in multiple separate processes and in some requiring holes punched into the label to achieve electrical contact and in other approaches additional components such as a paper or paper board or similar insulator component added to the voltage indicator in a separate process.

For purposes of quality control, ease of manufacture, manufacturing cost and design flexibility, it would be beneficial to produce a voltage indicator that is a fully contained device and is produced primarily by a roll to roll printing process. The present invention meets this need in the art.

### SUMMARY OF THE INVENTION

This invention features a voltage indicator device containing, in order, a pressure sensitive adhesive layer, a substrate, a conductive ink printed on the substrate, a dielectric ink printed on the conductive ink and substrate, and an insulation layer printed on the dielectric ink and substrate. In some embodiments, the voltage indicator device further includes a release liner substrate or a shrink film.

A shrink label containing the die cut voltage indicator device is also provided for application to a dry cell battery, wherein the die cut voltage indicator is applied to the shrink film with the pressure sensitive adhesive layer of the voltage indicator device. In one embodiment, the label is prepared from a machine direction shrink film including polyvinyl chloride, glycol-modified polyethylene terephthalate, oriented polystyrene, polypropylene, or polyethylene. In another embodiment, the label is a single layer or a laminate of one or more film layers. In a further embodiment, the shrink film is a polyethylene film produced by biaxial and subsequent machine direction uniaxial orientation. In yet further embodiments, the shrink film is transparent, opaque, metalized, embossed, or a combination thereof; or includes a surface lacquer, surface varnish, a graphic, a thermochromic ink, a reveal ink, or a combination thereof.

### BRIEF DESCRIPTION OF THE DRAWINGS

FIG. 1A depicts an exploded view of the components of a voltage indicator device of the invention.

FIG. 1B is a side view of the shrink label of the invention, where the voltage indicator device components are applied by a printing process onto a base substrate, which is then applied to the underside of a shrink film via a pressure sensitive adhesive. The shrink film with voltage indicator device is then applied to a battery.

### DETAILED DESCRIPTION OF THE INVENTION

The invention is a voltage indicator device and machine direction (MD) shrink label containing the voltage indicator device. The voltage indicator device of the invention is produced in an independent process where a pressure sensitive adhesive is applied to the voltage indicator device followed by a release liner. In accordance with this invention, the voltage indicator device is die cut and applied to a shrink label. After application of the voltage indicator device to the label, the label is die cut and applied to a battery.

The voltage indicator device is independently produced by printing the components of the voltage indicator onto the surface of a substrate, e.g., a plastic film or similar substrate, and applying a pressure sensitive adhesive and release liner to the opposite side of the substrate. The plastic film or substrate may be any plastic film such as polyethylene terephthalate (PET), oriented polystyrene (OPS), nylon, polypropylene (PP), polyethylene (PE), polyamide or equivalent substrate known as synthetic paper or other engineering films or specialty papers. However, the substrate is not a MD shrink film.

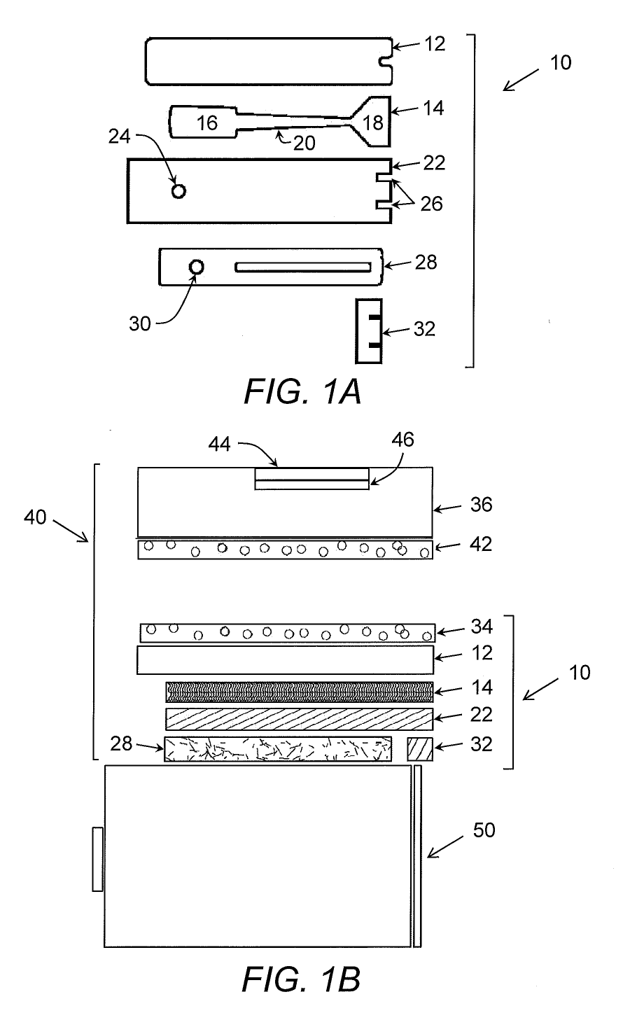

As illustrated in FIG. 1A, the voltage indicator device 10 contains a substrate 12, with a conductive ink layer 14 printed directly on the substrate. Conductive ink layer 14 is designed to incorporate a positive contact area 16, a negative contact area 18 and a gradient resistive area 20. The voltage indicator further includes a dielectric ink layer 22 printed on the conductive ink layer 14, wherein the dielectric ink layer 22 has open areas 24,26 for the positive 16 and negative 18 contacts of the conductive ink layer 14. Printed on the dielectric ink layer 22 is an insulating ink layer 28 with an open area 30 for the positive contact 16 of the conductive ink layer 14. Optionally, the voltage indicator device 10 also includes a flexible printed insulating ink layer 32 located in the negative contact area which is at the negative end of the battery and shrunk with the label around the bottom end of the battery. The conductive ink layer 14 positive contact 16, negative contact 18 and resistor 20 areas are designed to align with equivalent functioning areas in the printed label.

The conductive ink, dielectric ink and insulation layer are applied by a roll printing process. After printing the voltage indicator components on the substrate, a pressure sensitive adhesive 34 (FIG. 1B) of any suitable type is applied to the reverse or opposite side of substrate 12 as the voltage indicator components 14,22,28,32. A release liner is then applied to the pressure sensitive adhesive. Once the one or more components of the voltage indicator are printed on the substrate and the pressure sensitive adhesive and release liner are applied, the voltage indicator device is die-cut to form individual voltage indicator devices on a roll, which are available for dispensing by a process similar to pressure sensitive labeling.

As illustrated in FIG. 1B, the die-cut voltage indicator device 10 is applied to shrink film 36 thereby producing a battery label 40. To apply the label with the attached voltage indicator around the circumference of a battery 50, the label includes a pressure sensitive adhesive layer 42. In one embodiment, the pressure sensitive adhesive is the same adhesive used for applying the shrink label to the battery.

A thermochromic ink layer may also be included. In one embodiment, a thermochromic ink layer is incorporated into voltage indicator device and a reveal color is applied under the thermochromic layer, both of which are aligned with a clear or transparent window in the label. In another embodiment, the shrink label 40 has a thermochromic ink layer 44 and a color reveal ink layer 46 printed on the label (FIG. 1B). The thermochromic layer is applied by a roll printing process and may be included as part of the voltage indicator or the thermochromic layer may be part of the label with the voltage indicator aligned on the label to allow for effective thermal activation.

As indicated, the voltage indicator device contains several components. Required is a conductive ink, which conducts voltage or electrical energy from the battery and also contains the resistor function thereby generating heat as a function of the voltage level. The conductive ink can be silver, copper, graphene, organic-based or other similar materials used for printed electronics. Ink type, thickness and resistor circuit design are adjusted to achieve required dimensions and electronic and resistive properties. The conductive ink can also be selected as a function of the printing process, including flexo, gravure, or screen printing. An exemplary conductive ink is Henkel Electrodag PD 056, which is a silver-based conductive ink. In most instances, the conductive ink will require a thermal cure process to achieve an ultimate and stable conductivity and resistance. Thermal curing of the conductive ink can be achieved by oven curing, infrared (IR), near-infrared (NIR) or ultraviolet (UV) curing either in-line or in a separate thermal cure process. Typical cure temperatures are greater than 70° C. Post-printing thermal cure processes, such as a roll in an oven, are typically lower temperatures, i.e., 70-110° C. for longer periods of time, i.e., 1 hour to several days. In-line thermal curing processes require a shorter period of time and may use a hot air oven of up to several hundred feet in length. The in-line cure time is typically several minutes and is conducted at a temperature between 70-140° C. An in-line high energy lamp system such as IR, NIR, UV, or pulsed UV is typically less than a 1 second exposure and achieves temperatures much greater than 100° C. High energy lamp systems are typically designed to preferentially be absorbed by the conductive ink and not the substrate, adhesive or release liner. In a particularly suitable thermal cure scenario, the conductive ink is thermally cured to a stable resistance with no change in resistance at 70-100° C. exposure for up to 4 weeks and without thermal distortion of the substrate, adhesive or release liner.

The voltage indicator device also contains a dielectric ink to electrically insulate the conductive ink from the battery and other external exposures such as leaked alkali from the battery or high humidity. An exemplary dielectric ink includes Henkel Electrodag PD 1020A.

The voltage indicator device further includes a printed insulator material which is designed to create an insulation area between the resistor and thermochromic materials and the battery, which is a significant relative heat sink that negatively impacts the performance of the voltage indicator device. The insulator material is primarily to thermally insulate the resistor and heat generating function of the conductive layer from the thermal heat sink and thus heat extraction of the dry cell battery when the label and voltage indicator are tightly wrapped around the battery. The insulator layer may be designed to achieve 100 percent coverage of the resistor area or may have pores or holes or other insulating designs that are effective in achieving insulating performance. Materials for the insulating area can be of any variety or combination that provide effective thermal insulation between the battery and the conductive resistor area. An exemplary insulating material is Rucco UV960-UV298.

In addition, the voltage indicator device can contain flexible or elastomeric inks that maintain functionality and in particular may be used in an area where the label is heat shrunk around the contour of the battery.

The voltage indicator device can further include a material which is elastomeric in nature and may be used for thermal insulation or for an on/off touch mechanism.

The design and dimensions of the voltage indicator device can include a die cut design, where the device has dimensional spacing. Alternatively, the voltage indicator device can have a finger-like design (see FIG. 1), which is particularly advantageous when used in combination with a shrink label. In this embodiment, the shrink label undergoes uniform shrinkage in the negative contact area of the battery to form a desirable tight fit around the battery where the voltage indicator is comprised of a non-shrink substrate which does not inherently shrink or conform to the battery by a film shrinkage behavior. The die cut finger design of the voltage indicator device are adhered to the label and are allowed to dimensionally contract in conjunction with the shrink label to result in a uniformly heat shrunk combination.

As indicated, the label with integrated voltage indicator device also contains a reversible thermochromic ink and a corresponding reveal ink of a bright contrasting color. Typically, the reversible thermochromic ink is black or other dark color and is printed so that it is viewable from the outside of the label and the contrasting reveal or indicator color is printed underneath the thermochromic ink. Upon exposure to elevated temperature, the thermochromic ink changes from a black or dark color to a relatively transparent color, exposing the contrasting color to the outside direction of the label. The thermochromic ink may be selected to the desired temperature sensitivity, preferably with a transition temperature around 41° C. The thermochromic ink and contrasting indicator color may be applied to the label or the voltage indicator device. Inclusion in the label is the preferred design.

In some embodiments, the shrink film is a polyvinyl chloride (PVC), glycol-modified polyethylene terephthalate (PETG), biaxially oriented polystyrene (OPS), polypropylene (PP), or polyethylene (PE). In one embodiment, the label is a PE machine direction oriented (MDO) shrink film produced by biaxial and subsequent MD uniaxial orientation. Lamination of two PE MDO shrink films, or alternatively a PE MDO shrink and a PE biaxially-oriented non-shrink film is also embraced by the present invention. In some embodiments, the shrink film contains one or more additives.

The invention is described in greater detail by the following non-limiting examples.

### EXAMPLE 1

A design of the instant voltage indicator device is shown in FIG. 1A. Layer 12 is a PET film substrate, preferably of a thin thickness of less than 60 microns. Layer 14 is a silver conductive ink printed with the design shown. Layer 22 is a dielectric ink printed with a single hole so that the conductive material can make contact with the surface of the battery acting as an electrically positive contact. Layer 28 is an insulation ink printed with a hole to make an electrically positive contact with the battery and with an air gap to provide insulation at the conductive and heat generating resistor area. The fully printed design is die cut with pressure sensitive adhesive on a release liner. The electrically negative contact area design in FIG. 1A represents a finger design with three fingers where the finger end of the voltage indicator device will be aligned with the bottom of the battery shrink label. The holes in layers 22 and 28 are aligned to contact the circumference of the battery and results in an electrically positive connection to the battery when pressing on the label at this location. A typical transition temperature for the thermochromic ink is 41° C. The thermochromic ink and reveal color may alternatively be printed on the back or opposite side of the voltage indicator substrate and would be aligned with a clear or transparent window in the label.

The bottom of the label in the area of the fingers is wrapped and shrunk around the bottom end of the battery in contact with the negative end when pressing on the label at this location.

The conductive ink is thermally cured either in-line by IR, NIR or UV radiation or by a hot air oven in-line or subsequently in a roll. The fully completed and die cut voltage indicator device is then placed on the PS adhesive side of the shrink battery label with the resistor area in alignment with the thermochromic ink and color contrast indicator.

What is claimed is:

1. A die cut voltage indicator device comprising, in order, a pressure sensitive adhesive layer, a substrate layer, a conductive ink layer printed on the substrate, a dielectric ink layer printed on the conductive ink, and an one or more insulation layers printed on the dielectric ink wherein, in use, said insulation layer is in direct contact with the battery.

2. The die cute voltage indicator device of claim 1, further comprising a release liner.

3. The die cute voltage indicator device of claim 1, further comprising a shrink film.

4. The die cut voltage indicator device of claim 1, further comprising a thermochromic ink layer and a reveal layer under the thermochromic ink layer, wherein said thermochromic ink layer and reveal layer are applied to the voltage indicator substrate.

5. A die cut voltage indicator device consisting of, in order, a pressure sensitive adhesive layer, a substrate layer, a conductive ink layer printed on the substrate, a dielectric ink layer printed on the conductive ink, and an one or more insulation layers printed on the dielectric ink wherein, in use, said insulation layer is in direct contact with the battery.

6. A die cut shrink label comprising the die cut voltage indicator device of claim 1, a shrink film, a pressure sensitive adhesive, and a release liner for application to a dry cell battery, wherein the die cut voltage indicator is applied to the shrink film with the pressure sensitive adhesive layer of the voltage indicator device.

7. The die cut shrink label of claim 6, further comprising a thermochromic ink layer and reveal layer under the thermochromic ink layer, wherein said thermochromic ink layer and reveal layer are applied to the shrink label.

8. The die cut shrink label of claim 6, wherein the label is a machine direction shrink film comprising polyvinyl chloride, glycol-modified polyethylene terephthalate, biaxially oriented polystyrene, polypropylene, or polyethylene.

9. The die cut shrink label of claim 6, wherein the label is a single layer or a laminate of one or more layers.

10. The die cut shrink label of claim 6, wherein the shrink film is a polyethylene shrink film produced by biaxial and subsequent machine direction uniaxial orientation.

11. The die cut shrink label of claim 6, wherein the shrink film is transparent, opaque, metalized, embossed, or a combination thereof.

12. The die cut shrink label of claim 6, further comprising a surface lacquer, surface varnish, a graphic, a thermochromic ink, a reveal ink, or a combination thereof.
